(19) United States
(12) Patent Application Publication
(10) Pub. No.: US 2026/0118556 A1
(43) Pub. Date: Apr. 30, 2026

(54) METHOD AND DEVICE FOR THE POST-TREATMENT OF A FLUORIDE LAYER FOR AN OPTICAL SYSTEM FOR THE VUV WAVELENGTH RANGE, AND OPTICAL ELEMENT COMPRISING SAID FLUORIDE LAYER

(71) Applicant: Carl Zeiss SMT GmbH, Oberkochen (DE)

(72) Inventors: Felix Lange, Nattheim (DE); Alexander Wiegand, Oberkochen (DE); Marcel Haertling, Aalen (DE); Jens Luedecke, Aalen (DE); Aleksey Sidorenko, Aalen (DE); Nils Lundt, Ulm (DE); Maximillian Sender, Boebingen an der Rems (DE); Katja Schick, Aalen (DE); Konstantin Forcht, Aalen (DE); Dirk Isfort, Heidenheim (DE); Christian Sack, Schorndorf (DE)

(21) Appl. No.: 19/096,916

(22) Filed: Apr. 1, 2025

Related U.S. Application Data
(63) Continuation of application No. PCT/EP2023/077199, filed on Oct. 2, 2023.

(30) Foreign Application Priority Data
Oct. 5, 2022 (DE) 102022210512.5

(51) Int. Cl. G02B 1/12; G03F 7/00

(52) U.S. Cl. CPC G02B 1/12; G03F 7/706847

(57) ABSTRACT

A method for aftertreating a fluoride layer for an optical element for the use in the VUV wavelength range, which method comprises irradiating the fluoride layer with UV/VUV radiation in the presence of an active fluorination agent. An optical element with a fluoride layer is aftertreated using this method. An optical arrangement has at least one such optical element.

### CROSS-REFERENCE TO RELATED APPLICATIONS

The present application is a continuation of, and claims benefit under 35 USC 120 to, international application No. PCT/EP2023/077199, filed Oct. 2, 2023, which claims benefit under 35 USC 119 of German Application No. 10 2022 210 512.5, filed Oct. 5, 2022. The entire disclosure of each of these applications is incorporated by reference herein.

### FIELD

The disclosure relates to a method for aftertreating a fluoride layer for an optical element for the use in the VUV wavelength range. The disclosure also relates to an optical element with a fluoride layer that was aftertreated using this method, and to an optical arrangement for the VUV wavelength range, comprising at least one such optical element. The disclosure also relates to a device for aftertreating a fluoride layer for an optical element, which is designed for use in the VUV wavelength range.

In this application, the VUV wavelength range is understood to mean the wavelength range of electromagnetic radiation between 115 nanometers (nm) and 190 nm. The VUV wavelength range is relevant to microlithography for example. For instance, radiation in the VUV wavelength range is used in projection exposure apparatuses and wafer or mask inspection apparatuses, for example.

### BACKGROUND

Optical elements having at least one fluoride layer are frequently used in such apparatuses. Highly reflective optical elements for the VUV wavelength range typically have a fluoride layer, for example, in order to protect an underlying metal layer at which the radiation is reflected against oxidation. For instance, US 2017/0031067 A1 describes Al mirrors protected by an MgF₂ layer. Further, WO 2006/053705 A1 describes a protective layer made of chiolite for protecting a reflective metal layer from degradation. Moreover, DE 10 2018 211 499 A1 discloses a reflective optical element having a substrate, a metal layer, a metal fluoride layer applied to the metal layer and an oxide layer applied to the metal fluoride layer, and also a method for the production thereof. In this case, the oxide layer can reduce the degradation at the relatively high radiation intensities used in lithography and hence can extend the service life of the optical element. Layer stacks composed of different fluorides or fluorides and oxides may additionally also be used for the reflective coating or antireflective coating of optical elements.

However, the small band gap of most oxides can lead to a relatively high absorption in the VUV wavelength range. As a consequence, fluorides are commonly used as layer materials.

During the production of optical elements for the VUV wavelength range, fluoride layers are typically deposited using physical vapor deposition (PVD). For example, these methods include thermal evaporation, electron beam evaporation (EBPVD) and ion beam sputtering (IBS). Previously unsaturated bonds can be oxidized by oxygen or water, or saturated by OH groups, predominantly at the surface and optionally at grain boundaries and/or pores, either already during the coating (on account of the residual oxygen and water in the chamber) or at the latest following the exposure of the layers to ambient air. Accordingly, an oxyfluoride MₓO_{y}F_{z} (M=metal atom of the fluoride), a hydroxyfluoride Mₓ(OH)_{y}F_{z} or a mixture of both can form near the surface—and, in diffusion-driven fashion, along grain boundaries and/or pores. This oxidation/hydroxylation generally can lead to a reduction in the band gap and/or to the formation of localized defect states near the band edge. These two effects can cause increased extinction in the VUV wavelength range.

To reduce the absorption of the fluoride layers and the degradation thereof, it has been proposed to use an aftertreatment of the fluoride layers. Aftertreatment means that the treatment is implemented after the deposition of the fluoride layers has been completed.

For example, the article “Postfluorination of fluoride films for vacuum-ultraviolet lithography to improve their optical properties” by Y. Taki et al., Appl. Opt. 45, 1380 (2006) has disclosed a method for aftertreating fluoride layers (MgF₂, AlF₃, LaF₃) for optical elements for the VUV wavelength range and a corresponding device. The method described there consists of two steps: In the first step, the fluoride layers are exposed to gaseous F₂ at a temperature of 100° C., and low-fluorine regions are refluorinated as a result. In the second step, the fluoride layers are redensified at an elevated temperature of 300° C. and a lower concentration of F₂. The unwanted absorption of VUV radiation in the fluoride layers is significantly reduced as a result of the aftertreatment. Further, the irradiation stability of antireflective layers treated in this way, examined using long-term laser irradiation at 157 nm, is increased.

A similar method is also disclosed in JP 11140617 A. In the process, a metal fluoride layer applied to a substrate is heated to a temperature of between 100° C. and 700° C. in a chamber. Subsequently, a mixture of an inert gas and an active agent for fluorination, for example gaseous NF₃ or gaseous XeF₂, is introduced into the chamber, wherein the concentration of the active agent for fluorination lies between 1 vol. % and 20 vol. %, and the metal fluoride layer is exposed to this atmosphere for a predetermined period of time.

A method for postfluorination of fluoride layers is also described in US 2004/0006249 A1. Postfluorination can occur in the temperature range between 10° C. and 150° C. and a fluorine concentration of between 1000 ppm and 100%.

However, such known aftertreatment methods are typically performed at elevated temperature or in that effective aftertreatment uses an elevated temperature. This elevated temperature is typically accompanied by a number of potential issues. For instance, this can result in interdiffusion of layers, which may be accompanied by a loss of or a change in the optical effect. Further, an elevated temperature may also lead to the roughening of metallic layers (so-called hillock formation). In addition, the elevated temperature may also lead to the inclusion of stresses and/or relaxation. For example, cracks may form on account of different coefficients of thermal expansion of the individual layers and/or of the substrate.

Further, the literature describes that an aftertreatment in the form of subsequent irradiation with UV light may improve the optical performance of plasma. (ion-)assisted deposition fluorides deposited in the DUV wavelength range. For example, the article “Plasma-assisted deposition of metal fluoride coatings and modeling the extinction coefficient of as-deposited single layers”, M. Bischoff et al., Appl. Opt. 50, 232-238 (2010) describes the aftertreatment of metal fluoride layers with UV radiation that have been deposited by plasma-assisted electron beam deposition. The article showed that the initially poor transmission of LaF₃, MgF₂ and AlF₃ layers in the DUV wavelength range can be significantly increased by this aftertreatment. During this subsequent irradiation, color centers are bleached, and presumably unsaturated bonds are (superficially) post-oxidized.

While this procedure may be practicable for oxides in general and for fluorides for use in the DUV wavelength range (i.e. at wavelengths greater than 190 nm), it is generally eliminated for fluorides in the VUV wavelength range. In the latter case, oxidation can lead to the loss of optical performance.

DE 10 2021 200 490 A1 also describes an aftertreatment of a metal fluoride layer by irradiation, wherein electromagnetic radiation having at least one wavelength below 300 nm is used. The metal fluoride layer is applied on a metal layer of a reflective optical element for use in the UV wavelength range. The irradiation results in a passivation of the metal fluoride layer which counteracts degradation of the metal layer. However, the passivating protective layer is typically an oxide layer, which can lead to issues described above.

Irradiation with UV light may also be implemented supportingly with the deposition of layers, for nanostructuring or during the operation of a microlithography apparatus.

U.S. Pat. No. 7,798,096 B2 describes the use of UV light for assisting the deposition of high-k dielectrics via chemical vapor deposition or atomic layer deposition. In that case, the UV light is used to excite or ionize the process gas and thereby to initiate or enhance surface reactions during the deposition.

DE 10 2018 221 190 A1 further discloses the nanostructuring of a substrate for transmission of radiation in the FUV/VUV wavelength range by introducing an energy input, e.g. by irradiation with UV/VUV radiation. In that case, the substrate is crystalline; for example the substrate is an MgF₂ single crystal. The irradiation enables the surface of the MgF₂ single crystal to be reorganized in such a way that an antireflective effect occurs.

DE 10 2021 201 477 A1 also discloses a method for operating a microlithographic optical arrangement which has an optical element having a fluoride coating or composed of the fluoride substrate. In that case, for annealing defects of the fluoride, during operation, the optical element is irradiated with UV light with wavelengths which are greater than the wavelength of operating light of the optical arrangement, which is less than or equal to 300 nm.

Further methods for producing fluoride layers or optical elements with fluoride layers are known, in which other strategies are used to reduce the absorption and/or the degradation.

For example, DE 10 2005 017 742 A1 discloses a method for coating a substrate by plasma-assisted deposition of a coating material, for example a fluoride material. The plasma contains ions having a relatively low effective ion energy, while the effective energy per molecule is relatively high, which is intended to lead to low absorption and contamination of a deposited layer with at the same time a high packing density.

DE 10 2020 208 044 A1 discloses a method for producing an optical element, for example a mirror, window or beam splitter, for the VUV wavelength range having a coating with a fluorine scavenger layer, which can be applied to a fluoride layer. The purpose of the fluorine scavenger layer is to prevent the degradation of the fluoride layer, with an attendant longer lifetime of the optical element. The underlying mechanism is a significant reduction of the mobility of interstitial fluorine atoms by so-called fluorine scavengers in the fluorine scavenger layer.

Further variants of physical vapor deposition for fluoride layers are also described in US 2013/0122252 A1, JP 11172421A and JP 2003193231A2.

### SUMMARY

The disclosure seeks to provide a method for aftertreating fluoride layers for the VUV wavelength range and a corresponding device, in which the aftertreated fluoride layers have a relatively high optical performance, for example relatively low and relatively long-term-stable absorption.

According to a first aspect, the disclosure provides a method for aftertreating a fluoride layer for an optical element for the use in the VUV wavelength range, comprising the step of irradiating the fluoride layer with UV/VUV radiation in the presence of an active fluorination agent.

In the context of this application, UV/VUV radiation denotes electromagnetic radiation in the wavelength range between 115 nm and 350 nm. The fluoride layer can be irradiated with VUV radiation in the wavelength range between 115 nm and 190 nm in the presence of an active fluorination agent.

The active fluorination agent can be a gaseous substance which as a consequence of irradiation by UV/VUV radiation forms molecular and/or atomic, optionally also ionized and/or excited, fluorine (referred to as fluorine species in encompassing fashion below). The fluorine species formed thus can lead to the refluorination of the oxyfluoride/hydroxyfluoride at the surface or in the fluoride layer.

As a consequence of the refluorination, the reflectance (or the transmittance) of the optical elements can be significantly increased and long-term stable. This can be accompanied by a significantly increased system transmission of optical arrangements for the VUV wavelength range, having at least one optical element with a fluoride layer aftertreated thus, leading for example in the case of VUV microlithography apparatuses to a higher throughput.

Furthermore, this can significantly reduce the heating of the optical elements during operation (also referred to as “lens heating”). This can be connected firstly with a reduction of the imaging aberrations caused by lens heating. Further, the reduced lens heating can be accompanied by a lengthening of the service life of the optical elements since thermally activated processes that drive the degradation of the optical elements proceed more slowly. For example, these include diffusion processes with Arrhenius-type activation, i.e. D∝exp(−E_{D}/k_{B}T), where D is the diffusion coefficient, E_{D} is the activation energy for diffusion, k_{B} is the Boltzmann constant and T is the temperature.

Compared to certain known methods for aftertreating fluoride layers, the method according to the disclosure can manage without elevated temperature and is able to avoid issues connected therewith.

In a variant of this method, the UV/VUV radiation has a first spectral range for photodissociation of the active fluorination agent, comprising at least one wavelength whose energy, Eₚₕ, is at least equal to the dissociation energy, E_{diss}, of the active fluorination agent. The dissociation energy, E_{diss}, in this case denotes the energy involved to split the chemical bond of the active fluorination agent via electromagnetic radiation (light).

The first spectral range can mainly comprise, optionally exclusively comprise, wavelengths whose energy, Eₚₕ, is at least equal to the dissociation energy, E_{diss}, of the active fluorination agent. In this case, the following relation applies to all photons of the first spectral range:

$${E}_{diss} \leq {E}_{ph} .$$

It may be desirable to limit the first spectral range toward higher energies, in such a way that potentially negative and/or competing effects are suppressed or reduced in terms of their rate. Thus, E_{UP} can be chosen to be less than a threshold energy, above which negative and/or competing effects are amplified or only occur in the first place, where E_{UP} is the highest energy of the first spectral range, i.e. Eₚₕ≤E_{UP} applies. Examples of such negative and/or competing effects include the absorption of light in the solid body and the photodissociation of potentially oxidizing species (e.g. O₂ and H₂O) in the gaseous phase.

In a development of this variant, the highest energy, E_{UP}, of the first spectral range is no more than 100%, such as no more than 50%, greater than the dissociation energy, E_{diss}, of the active fluorination agent.

In a further variant of this method, the highest energy (E_{UP}) of the first spectral range is no more than the band gap energy, E_{G}, of the fluoride layer, such as no more than 75% of the band gap energy, E_{G}, of the fluoride layer. This can reduce the photoabsorption in the solid.

To reduce the photodissociation of potentially oxidizing species (e.g. O₂ and H₂O) in the gaseous phase, it can be desirable to limit the first spectral range to lower and higher energies, in such a way that the effective rate of formation of potentially fluorinating species r_{fluorinating}, such as e.g. F, F₂, F⁻, F* or HF, is greater than the rate of potentially oxidizing species r_{oxidizing}, such as e.g. O, O₂, O*, O⁻, OH* and OH⁻:

$${r}_{fluorinating} > {r}_{oxidizing} .$$

In a further variant of this method, the UV/VUV radiation includes a second spectral range for mobilizing atoms at the surface, at the grain boundaries and/or in the grain volume of the fluoride layer, the second spectral range lying in an energy range of between 75% and 100%, such as between 80% and 95%, of a band gap energy of the fluoride layer. For example, the energy of the light in the second spectral range is higher than the binding energy of the corresponding atoms in the solid.

High-energy electromagnetic radiation near the band edge of the fluoride can make it possible for surface atoms or atoms to be mobilized, without these atoms being desorbed, as described for example in DE 10 2018 221 190 A1, cited in the introduction. This increased mobility may contribute to transporting the active fluorination agent offered superficially or the fluorine species into the volume of the fluoride layer as well, presumably predominantly via grain boundaries. Hence, depth fluorination may be assisted in this way, whereby the optical performance is improved. Moreover, it is possible that intrinsic point defects in the grain volume may be addressed by way of this increased diffusion.

In a further variant of this method, the fluoride layer is an AlF₃ layer. While the method is suitable in general for the aftertreatment of any type of fluoride layers (e.g. of MgF₂, LaF₃, . . . ), it was found to be particularly suited for AlF₃ layers. The reason for this would appear to lie in the special structure of AlF₃ thin layers. AIF; is one of a few fluorides that forms an x-ray amorphous structure. This structure is composed locally of different, energetically similar, AlF₃ polymorphs. These various structural motifs are linked to one another via their edges. The pronounced disorder resulting therefrom can intrinsically offer many unsaturated bonds, which can be passivated by oxygen or hydroxyl groups. These AlₓO_{y}F_{z} and AlₓOH_{y}F_{z} agents, which are intrinsically present in a deposited AlF₃ thin film following a coating process, can be effectively converted into AlF₃ using the method according to the disclosure—with the corresponding improvement in the optical performance in the VUV wavelength range.

The method is also suitable for the aftertreatment of fluoride layers containing at least one fluoride from the following group: magnesium fluoride, aluminum fluoride, sodium fluoride, lithium fluoride, chiolite, cryolite, calcium fluoride, erbium fluoride, neodymium fluoride, gadolinium fluoride, dysprosium fluoride, samarium fluoride, holmium fluoride, hafnium fluoride, lanthanum fluoride, europium fluoride, lutetium fluoride, cerium fluoride, barium fluoride, strontium fluoride, and yttrium fluoride.

In a further variant of this method, the UV/VUV radiation or further electromagnetic radiation additionally used to irradiate the fluoride layer includes a spectral range for annealing at least one crystal defect of the fluoride layer, at least partly overlapping with an absorption range of the at least one crystal defect, the spectral range optionally comprising an absorption energy of the crystal defect, a mean energy of the spectral range optionally deviating from the absorption energy of the crystal defect by no more than 0.5 eV, such as by no more than 0.25 eV.

A potential issue with the irradiation by VUV radiation is that the latter may cause crystal defects, for example F/H center defect pairs, in the fluoride by way of single-photon processes. These crystal defects can be annealed by the irradiation in a spectral range that at least partly overlaps with the absorption range.

The absorption energy of the crystal defect is understood to mean that energy or wavelength at which the absorption coefficient of the crystal defect has a maximum. The absorption range of the crystal defect is understood to mean a range in which the absorption coefficient is greater than one hundredth of the value at the maximum of the absorption coefficient. The absorption energies of crystal defects of a plurality of fluorides that are relevant to the present applications are indicated below by way of example: MgF₂: 260 nm (4.77 electron-Volt (eV)), AlF₃: 190 nm (6.53 eV), 170 nm (7.29 eV), LaF₃: 459 nm (2.7 eV), 564 nm (2.2 eV), 729 nm (1.7 eV).

In a further variant of this method, the fluoride layer is irradiated in a protective gas atmosphere. The protective gas can be transparent to electromagnetic radiation in the UV/VUV wavelength range. Further, protective gases that are comparatively unreactive vis-à-vis the optically relevant oxides and fluorides can be used. Inert gases in the form of the light noble gases—helium, neon and argon—are suitable as protective gas, with argon being particularly well suited. Mixtures of noble gases, for example of the noble gases mentioned, can also be used as protective gas. The fluoride layer is typically irradiated in an aftertreatment chamber with that protective gas atmosphere in its interior.

In a further variant of this method, the oxygen concentration during the irradiation of the fluoride layer is less than 10 parts per million by volume (ppmV), such as less than 1 ppm V, for example less than 100 parts per billion by volume (ppbV), for example less than 50 ppbV, in the surroundings of the fluoride layer. The oxygen concentration in the surroundings of the fluoride layer should be as low as possible during the irradiation.

In a further variant of this method, the H₂O concentration during the irradiation of the fluoride layer is less than 10 ppmV, such as less than 1 ppm V, for example less than 500 ppbV, for example less than 100 ppbV, in the surroundings of the fluoride layer. A potential issue of higher H₂O concentrations is that water is a source of hydrogen under photodissociation that reacts with the fluorine formed from the active fluorination agent to form HF, e.g.:

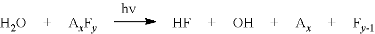

Therefore, the H₂O concentration should be kept as low as possible during the irradiation.

Moreover, photocontamination sources can be excluded from the process to the greatest possible extent. This applies for example to carbon compounds and silanes.

In a further variant of this method, the active fluorination agent comprises at least one substance selected from the group of: F₂, HF, XeF₂, NF₃, CF₄, SF₆.

In a further variant of this method, the partial pressure of the active fluorination agent lies between 0.05 and 10⁶ ppm V, such as between 0.075 ppmV and 50 ppm V, for example between 0.1 ppm V and 10 ppmV, during the irradiation of the fluoride layer.

In a further variant of this method, the partial pressure of the active fluorination agent is adjusted to a target value during the irradiation of the fluoride layer.

In a further variant of this method, the fluoride layer is heated during the irradiation. Refluorination of the fluoride layer is assisted by the heating. In comparison with the known methods, described further above, for refluorination, however, a better fluorination effect is obtained at the same temperatures, or the temperature may be chosen to be substantially lower.

Furthermore, the fluorination process can be assisted via a plasma.

A further aspect of the disclosure relates to an optical element for use in the VUV wavelength range, comprising a fluoride layer that was aftertreated or is aftertreated using the above-described method.

The optical element may be a reflective optical element for example. For example, the optical element may comprise a metal layer, applied to a substrate, for reflecting electromagnetic radiation in the VUV wavelength range, wherein the fluoride layer is applied onto the metal layer in order to protect the latter. The aftertreatment using the aftertreatment method according to the disclosure can lead to an improved optical performance of the optical element in the process. For example, the reflectance thereof in the VUV wavelength range can be significantly higher than before the aftertreatment and is stable against environmental influences. However, the optical element may also be a transmissive optical element, to which a dielectric multilayer coating containing one or more fluoride layers is applied. For example, the multilayer coating may have an antireflective function.

According to a further aspect, the disclosure provides an optical arrangement for the VUV wavelength range, for example a VUV lithography apparatus or a wafer inspection system, comprising: at least one optical element as described above. The optical arrangement may, for example, be a (VUV) lithography system, a wafer or mask inspection system, a laser system, etc.

According to a further aspect, the disclosure provides a device for aftertreating a fluoride layer for an optical element, which is designed for use in the VUV wavelength range, comprising: an aftertreatment chamber; a supply unit for supplying inert gas and an active fluorination agent into the aftertreatment chamber, the inner side of the aftertreatment chamber being resistant to the active fluorination agent and its conversion products; and at least one UV/VUV radiation source for irradiating the fluoride layer with UV/VUV radiation in the presence of the active fluorination agent in the aftertreatment chamber. With regard to the features achieved with the device, reference should be made to the above explanations regarding the method and its variants.

The UV/VUV radiation emitted by the UV/VUV radiation source is partly absorbed by the active fluorination agent. The fluorine species formed as a consequence by photodissociation of the active fluorination agent can bring about a refluorination of the fluoride layer.

The UV/VUV radiation source can have a first spectral range for photodissociation of the active fluorination agent. The wavelengths of the radiation emitted by the UV/VUV radiation source can lie between 115 nm and 1000 nm, such as between 120 nm and 170 nm, for example between 140 nm and 170 nm. For example, the UV/VUV radiation source may comprise a D₂ lamp (deuterium arc lamp), an Xe gas discharge lamp or an Hg vapor lamp. Alternatively, an F2 excimer laser (at a wavelength of 157 nm) may also be used.

The aftertreatment chamber may be sealed in a gas-tight manner. The conversion products of the active fluorination agent mean the fluorine species and the chemical compounds formed therefrom (for example HF). Stability should be understood for example in the sense that a passivating layer is formed on the inner side of the aftertreatment chamber. For example, there is no formation of volatile fluorine compounds that can be precipitated on the optical element. The aftertreatment chamber, especially the inner side thereof, can for example be manufactured at least partly from a metallic material which should typically be free of Cr and Ti, in order to prevent corrosion. The aftertreatment chamber may have been manufactured from Monel steel for example.

Alternatively, the inner side of the aftertreatment chamber may have a fluorine-stable coating in order to prevent corrosion. Such a coating can be applied by a galvanic process. Suitable materials are NiP, Pt or Ru/Rh mixtures for example.

The supply unit can be designed to introduce the active fluorination agent, diluted in the inert gas, into the aftertreatment chamber. Furthermore, the supply unit may comprise a suitable metering valve, for example a mass flow controller, in order to set the partial pressure of the active fluorination agent in the aftertreatment chamber to a desired value.

The device can moreover comprise a fluorine gas sensor and/or a dedicated sensor for the active fluorination agent. The device may further comprise a closed-loop controller for controlling the partial pressure of the active fluorination agent, control optionally being brought about via the measured values from the fluorine gas sensor and/or dedicated sensor for the active fluorination agent.

Hence, the partial pressure of the active fluorination agent may firstly be set indirectly by setting the flow or else be actively controlled by way of a sensor and a closed-loop controller.

The device can comprise one or more further fluorine-resistant sensors for determining the O₂ and/or the H₂O partial pressure in the aftertreatment chamber.

The device may optionally comprise a second UV/VUV radiation source that emits UV/VUV radiation in a second spectral range for the purpose of mobilizing atoms at the surface and/or in the volume of the fluoride layer, as described further above in the context of the method. In an alternative to that, the device may also comprise only one UV/VUV radiation source that emits UV/VUV radiation in the first and second spectral ranges.

In order to anneal at least one crystal defect of the fluoride layer, the UV/VUV radiation source and/or the second UV/VUV radiation source may further optionally emit in a spectral range that at least partly overlaps with the absorption range of the at least one crystal defect. In an alternative to that, the device may also comprise one or more further radiation sources that serve to anneal the at least one crystal defect and emit further electromagnetic radiation in a spectral range that at least partly overlaps with the absorption range of the at least one crystal defect. Thus, at least one radiation source can be suitable for bleaching crystal defects that arise in the fluoride layer and/or the substrate during the refluorination. The spectral ranges can be adaptable to the absorption range or the absorption ranges of the crystal defects. For example, the further radiation source or further radiation sources may be one or more tunable radiation sources (for example based on a broadband primary light source with a downstream wavelength selection). In an alternative to that or in addition, a dedicated radiation source may also be used for the fluoride to be refluorinated or for each of the fluorides to be refluorinated.

Further features and aspects of the disclosure are evident from the following description of exemplary embodiments of the disclosure, with reference to the figures of the drawing, which show details relevant to the disclosure, and from the claims. The individual features can be implemented individually in their own right or collectively in any combination in a variant of the disclosure.

### BRIEF DESCRIPTION OF THE DRAWINGS

Exemplary embodiments are shown in the schematic drawings and are explained in the description which follows.

FIG. 1 shows a schematic illustration of the aftertreatment of a fluoride layer for an optical element for the use in the VUV wavelength range using the aftertreatment method according to the disclosure.

FIG. 2 shows a schematic illustration of the absorption and spectral ranges relevant to the irradiation of the fluoride layer using the aftertreatment method.

FIG. 3 shows a schematic illustration of a device for aftertreating a fluoride layer for an optical element, which is designed for use in the VUV wavelength range.

FIG. 4 shows a schematic illustration of an optical arrangement for the VUV wavelength range in the form of a VUV lithography apparatus.

FIG. 5 shows a schematic illustration of an optical arrangement for the VUV wavelength range in the form of a wafer inspection system.

FIG. 6 shows a schematic illustration of an optical element with a fluoride layer, which was aftertreated using the method according to the disclosure.

### DETAILED DESCRIPTION

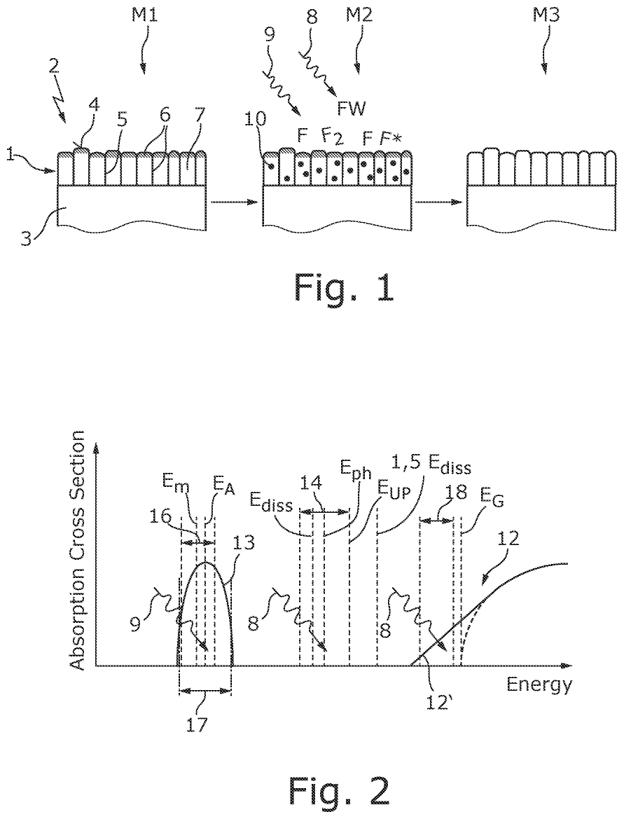

FIG. 1 shows a schematic illustration of the aftertreatment of a fluoride layer 1 of an optical element 2 for use in the VUV wavelength range. The fluoride layer 1 of the optical element 2 that is applied to a substrate 3 is depicted at three snapshots M1, M2, M3, before the aftertreatment (snapshot M1), during the aftertreatment (snapshot M2) and after the aftertreatment (snapshot M3), with only a small portion of a surface 4 of the fluoride layer 1 facing the environment being shown in each case.

Prior to the aftertreatment (first snapshot M1), an oxyfluoride or hydroxyfluoride or a mixture of both is present on the surface 4 of the fluoride layer 1 and along grain boundaries 5 of the fluoride layer 1 on account of the exposure of the fluoride layer 1 e.g. to ambient air. For example, the fluoride layer 1 is superficially oxidized due to the saturation of previously unsaturated bonds and has defect-rich grain boundaries 5 with unsaturated bonds and/or bonds saturated by O or OH from the atmosphere. These at least partially oxidized or defect-rich regions 6 can have an undesirable effect on the optical performance of the optical element 1. By contrast, a stoichiometric fluoride is typically present in the grain volume 7.

For the aftertreatment, the fluoride layer 1 or the substrate 3 with the fluoride layer 1 applied thereto is initially transferred into an aftertreatment chamber, which is not depicted in FIG. 1. Subsequently, as shown in the second snapshot M2, the fluoride layer 1 is irradiated with UV/VUV radiation 8 in the presence of an active fluorination agent FW. As a consequence of the irradiation, the active fluorination agent FW dissociates and forms fluorine species F, F₂, F*. The fluorine species F, F₂, F* react with the at least partially oxidized or defect-rich regions 6, and a fluoride is formed there. By way of example, the active fluorination agent FW is NF₃, but it may also be a different substance that is able to provide the fluorine species F, F₂, F* by way of photodissociation, for example at least one substance from the group comprising: F₂, HF, XeF₂, CF₄ and SF₆.

Furthermore, the fluoride layer 1 is irradiated by further electromagnetic radiation 9 during the aftertreatment in the example illustrated, but this is not mandatory. This serves the annealing of crystal defects 10 in the fluoride layer 1.

Moreover, the fluoride layer 1 may additionally be heated during the irradiation, although this is not depicted in FIG. 1. However, heating is not a mandatory constituent of the method.

The at least partially oxidized or defect-rich regions 6 of the fluoride layer 1 are refluorinated following the aftertreatment (third snapshot M3). Now, an (at least approximately) stoichiometric fluoride is present there as well. As a consequence, the optical performance of the optical element 2 is significantly improved and comparatively stable in relation to environmental influences.

FIG. 2 illustrates the absorption and spectral ranges relevant to the irradiation of the fluoride layer 1. Energy is plotted on the abscissa axis, and the absorption cross section is plotted on the ordinate axis. The dissociation energy E_{diss} of the active fluorination agent FW, the absorption cross section 12 of the fluoride layer 1, including an Urbach tail 12′, and the absorption cross section 13 of a crystal defect 10 in the fluoride layer 1 are depicted schematically.

The VUV radiation 8 used to irradiate the fluoride layer 1 has a first spectral range 14 for the photodissociation of the active fluorination agent FW. By way of example, the first spectral range 14 comprises at least one wavelength whose energy Eₚₕ is at least equal to the dissociation energy E_{diss} of the active fluorination agent FW. Further, the highest energy E_{UP} of the first spectral range 14 is here by way of example, but not necessarily, less than 50% greater than the dissociation energy E_{diss} of the active fluorination agent FW. This suppresses potentially negative and/or competing effects. The highest energy E_{UP} of the first spectral range 14 may also be no more than the band gap energy E_{G} of the fluoride layer 1, such as no more than 75% of the band gap energy E_{G} of the fluoride layer 1.

Moreover, the fluoride layer 1 is irradiated with further electromagnetic radiation 9 by way of example for annealing at least one crystal defect 10 in the fluoride layer 1. To this end, the further electromagnetic radiation 9 includes a spectral range 16 that overlaps with the absorption range 17 of the at least one crystal defect 10. In the illustrated example, the spectral range 16 of the further electromagnetic radiation 9 lies within the absorption range 17 of the crystal defect 10, which is an F center; however, this is not necessarily required. In an alternative to that, the UV/VUV radiation 8 may include a corresponding spectral range.

In the illustrated example, the spectral range 16 of the further electromagnetic radiation 9 comprises the absorption energy EA of the crystal defect 10 at which the absorption cross section is maximal. However, this is not necessarily the case. The absorption range 17 of the crystal defect 10 is defined by a drop to one hundredth of the maximum value of the absorption cross section (FWHM) at the absorption energy E_{A} of the crystal defect 10. Further, it is desirable if a mean energy Eₘ of the spectral range 16 deviates from the absorption energy E_{A} of the crystal defect 10 by no more than 0.5 eV, for example by no more than 0.25 eV.

Moreover, the UV/VUV radiation 8 includes a second spectral range 18 for mobilizing atoms at the surface 4, at the grain boundaries 5 and/or in the grain volume 7 of the fluoride layer 1. In the illustrated example, this second spectral range 18 lies in an energy range of between 75% and 100% of the band gap energy E_{G} of the fluoride layer 1. The second spectral range 18 may also lie between 80% and 95% of the band gap energy E_{G} of the fluoride layer 1.

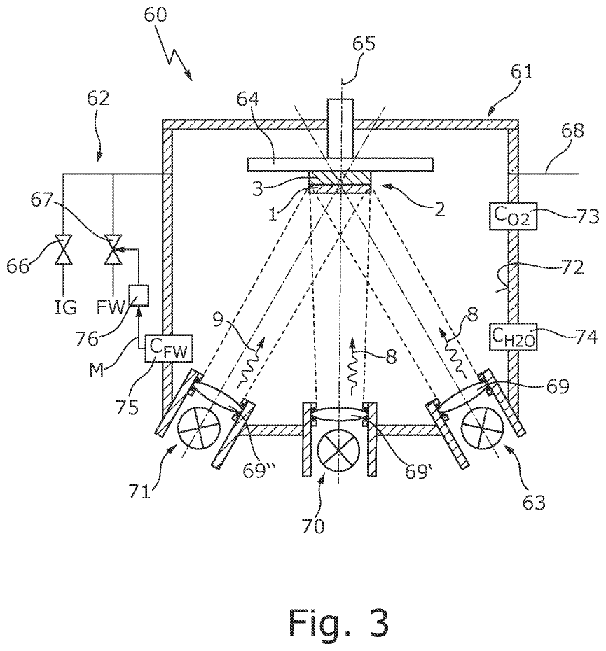

FIG. 3 shows a device 60 for aftertreating the fluoride layer 1 for the optical element 2 of FIG. 1 using the above-described aftertreatment method. The device 60 comprises an aftertreatment chamber 61, a supply unit 62 and a first UV/VUV radiation source 63.

The optical element 2 that comprises the fluoride layer 1, which is applied to a substrate 3 in exemplary fashion in this case, is attached to a substrate holder 64, which is rotatable about a rotation axis 65, within the aftertreatment chamber 61. However, deviating from the example illustrated here, the device 1 need not comprise a rotatable substrate holder 64.

The supply unit 62 serves to supply protective gas in the form of inert gas IG and the active fluorination agent FW into the aftertreatment chamber 61, the supply unit 62 comprising a first valve 66 for controlled supply of the inert gas IG and a second valve 67 for controlled supply of the active fluorination agent FW. The second valve 67 is a controllable metering valve. As a consequence, the fluoride layer 1 may be irradiated in the presence of the active fluorination agent FW in a protective gas atmosphere within the aftertreatment chamber 61. The device 60 moreover comprises a gas outlet 68 for letting out the inert gas IR and reaction products formed during the aftertreatment. In the example illustrated, the inert gas IR is argon, but it is also possible to use other inert gases IR, for example other light noble gases such as helium or neon. Mixtures of noble gases, for example of the noble gases mentioned, can also be used as inert gas IR.

The first UV/VUV radiation source 63 serves to irradiate the fluoride layer 1 with UV/VUV radiation 8 in the presence of the active fluorination agent FW in the aftertreatment chamber 61. By way of example, in the illustrated example, the UV/VUV radiation 8 enters the aftertreatment chamber 61 through an MgF₂ window 69. The first UV/VUV radiation source 63 serves to generate UV/VUV radiation 8 in the first spectral range 14 described further above.

Moreover, by way of example, the device 60 in this case comprises, but not necessarily, a second UV/VUV radiation source 70 for irradiating the fluoride layer 1 with UV/VUV radiation 8 in the second spectral range 18, described further above, for mobilizing atoms at the surface 4, at the grain boundaries 5 and/or in the grain volume 7 of the fluoride layer 1. In the illustrated example, the UV/VUV radiation from the second UV/VUV radiation source 8 enters the aftertreatment chamber 61 through an MgF₂ window 69′. The device 60 also comprises a further radiation source 71 for irradiating the fluoride layer 1 with further electromagnetic radiation 9 in the spectral range 17, described further above in the context of FIG. 2, for annealing at least one crystal defect 10 in the fluoride layer 1. The further electromagnetic radiation 9 from the further radiation source 71 enters the aftertreatment chamber 71 through a further MgF₂ window 69″.

In place of at least one of the MgF₂ windows 69, 69′, 69″, it is possible in principle to also use windows made of other materials, for example from CaF₂, SrF₂ and/or BaF₂, with sufficient transparency at the utilized wavelengths being decisive in this respect.

The aftertreatment chamber 61 may be sealed in a gas-tight manner. Furthermore, the inner side 72 of the aftertreatment chamber 61 is resistant to the active fluorination agent FW and its conversion products. For this purpose, in the example illustrated, the aftertreatment chamber 61, at least on its inner side 72, is formed from a metal in the form of Monel steel, which forms a passivating layer in order to prevent corrosion. In principle, the aftertreatment chamber 61 can also be formed from other corrosion-resistant metals if the latter are free of Cr and Ti.

Alternatively, a corrosion-resistant coating, e.g. composed of NiP, Pt or Ru/Rh mixtures, can be applied to the inner side 72 of the aftertreatment chamber 61. The corrosion-resistant coating can be applied to the inner side 72 of the aftertreatment chamber 61 via a galvanic process, for example. The components which are arranged in the aftertreatment chamber 61 and which come into contact with the active fluorination agent FW are likewise resistant to the active fluorination agent FW and the conversion products thereof.

Further the device 60 depicted here comprises, by way of example, but not necessarily, a sensor 73 for measuring the oxygen concentration c_{O2} in the aftertreatment chamber 61 and a further sensor 74 for measuring the H₂O concentration c_{H2O} in the aftertreatment chamber 61.

By way of example, the oxygen concentration coz in the aftertreatment chamber 61 is less than 50 ppb V during the irradiation of the fluoride layer 1. The oxygen concentration c_{O2} should be as low as possible, although it may also be greater than 50 ppbV. However, it is desirable for the oxygen concentration coz to be less than 10 ppmV, such as less than 1 ppm V, for example less than 100 ppb V.

Further, in the illustrated example, the H₂O concentration c_{H2O} in the aftertreatment chamber 61 is less than during the irradiation of the fluoride layer 1 In principle, the H₂O concentration c_{H2O} in the aftertreatment chamber 61 during the irradiation of the fluoride layer 1 should be as low as possible, although the H₂O concentration c_{H2O} may also be greater than 100 ppbV. However, it is desirable for the H2O concentration c_{H2O} to be less than 10 ppm V, such as less than 1 ppm V, for example less than 500 ppb V.

The device 60, in the illustrated example, but not necessarily, moreover comprises a sensor 75 for measuring the partial pressure c_{FW} of the active fluorination agent FW in the aftertreatment chamber 61 and a closed-loop controller 76 for controlling the partial pressure c_{FW} of the active fluorination agent FW in the aftertreatment chamber 61 to a target value, the control being implemented using the actual measured value M from the sensor 75 for measuring the partial pressure c_{FW} of the active fluorination agent FW in the aftertreatment chamber 61 and via the control of the second valve 67. The sensor 75 may be designed only to measure the partial pressure c_{FW} of the active fluorination agent FW; however, it may also be a residual gas analyzer that is able to also determine the partial pressures of other gases contained in the aftertreatment chamber 21. It is possible that such a residual gas analyzer assumes the function of the three sensors 73, 74, 75 depicted in FIG. 3. If the second valve 67 is a metering valve, for example a mass flow regulator, then it is possible to dispense with the use of the sensor 75 for measuring the partial pressure c_{FW} of the active fluorination agent FW in the aftertreatment chamber 61.

The active fluorination agent FW is added to the inert gas IR in the supply unit 62. The partial pressure c_{FW} of the active fluorination agent FW in the aftertreatment chamber 61 lies typically between 0.05 and 10⁶ ppmV, such as between 0.075 ppm V and 50 ppmV, for example between 0.1 ppmV and 10 ppmV, during the irradiation of the fluoride layer 1.

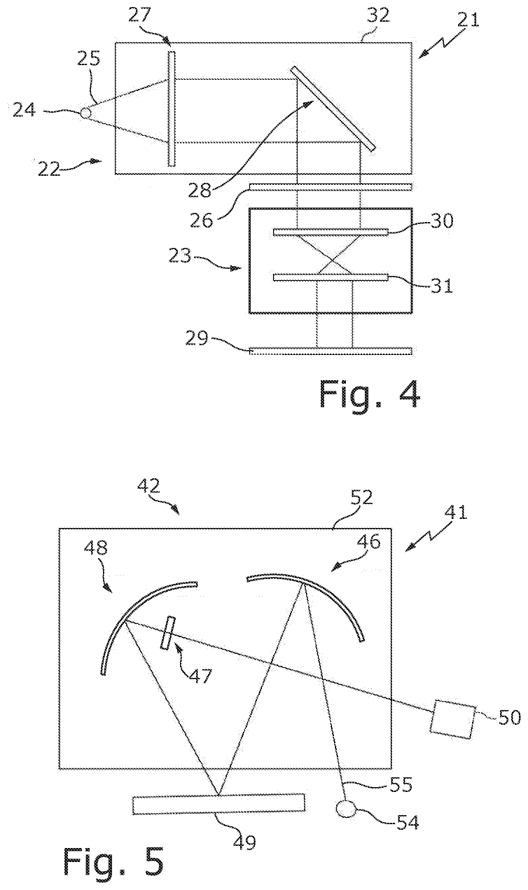

FIG. 4 shows an optical arrangement for the VUV wavelength range in the form of a VUV lithography apparatus 21. The VUV lithography apparatus 21 comprises two optical systems, namely an illumination system 22 and a projection system 23. The VUV lithography apparatus 21 additionally comprises a radiation source 24, which may be an excimer laser, for example.

The radiation 25 emitted by the radiation source 24 is conditioned with the aid of the illumination system 22 such that a mask 26, also called a reticle, is illuminated thereby. In the example shown, the illumination system 22 comprises a housing 32, in which both transmissive and reflective optical elements are arranged. In a representative manner, the illustration shows a transmissive optical element 27, which focuses the radiation 25, and a reflective optical element 28, which deflects the radiation.

The mask 26 comprises, on its surface, a structure which is transferred to an optical element 29 to be exposed, for example a wafer, with the aid of the projection system 23 for the purpose of producing semiconductor components. In the example shown, the mask 26 is designed as transmissive optical element. In alternative embodiments, the mask 26 may also be designed as reflective optical element.

The projection system 22 comprises at least one transmissive optical element in the example illustrated. The example shown illustrates, in a representative manner, two transmitting optical elements 30, 31, which serve, for example, to reduce the structures on the mask 26 to the size desired for the exposure of the wafer 29.

Both in the illumination system 22 and in the projection system 23, a wide variety of transmissive, reflective or other optical elements can be combined with one another as desired, including in a more complex manner. Optical arrangements without transmissive optical elements can also be used for VUV lithography.

FIG. 5 shows an optical arrangement for the VUV wavelength range in the form of a wafer inspection system 41, but this may also be a mask inspection system. The wafer inspection system 41 comprises an optical system 42 with a radiation source 54, from which the radiation 55 is directed onto a wafer 49 via the optical system 42. For this purpose, the radiation 55 is reflected off a concave mirror 46 to the wafer 49. In the case of a mask inspection system, it would be possible to replace the wafer 49 with a mask to be examined. The radiation reflected, diffracted and/or refracted by the wafer 49 is directed onto a detector 50 for further evaluation by a further concave mirror 48, which is likewise associated with the optical system 42, via a transmissive optical element 47. The wafer inspection system 41 additionally comprises a housing 52, in which the two mirrors 46, 48 and the transmissive optical element 47 are arranged. The radiation source 54 may, for example, be exactly one radiation source or a combination of a plurality of individual radiation sources in order to provide a substantially continuous radiation spectrum. In modifications, it is also possible to use one or more narrowband radiation sources 54.

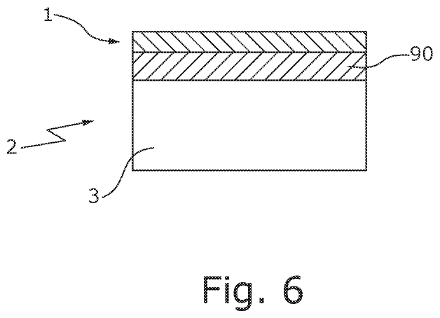

At least one of the optical elements 27, 28, 30, 31 of the VUV lithography apparatus 21 shown in FIG. 5 and at least one of the optical elements 46, 47, 48 of the wafer inspection system 41 shown in FIG. 6 are designed here as described further above. The at least one of the optical elements 27, 28, 30, 31 thus comprises at least one fluoride layer that was aftertreated using the above-described method.

FIG. 6 shows an optical element 2 for the VUV wavelength range in the form of an Al mirror which comprises an Al layer 90 applied to a substrate 3 and which is protected by a fluoride layer 1 in the form of an AlF₃ layer. The fluoride layer 1 was aftertreated using the above-described method. As a consequence, the reflectance of the optical element 2 is increased, and the degradation during the operation of the optical element 2 is reduced.

What is claimed is:

1. A method, comprising:
irradiating a fluoride layer of an optical element with UV/VUV radiation in the presence of an active fluorination agent,
wherein the active fluorination agent comprises at least one member selected from the group consisting of F₂, HF, XeF₂, NF₃, CF₄ and SF₆.

2. The method of claim 1, wherein the UV/VUV radiation has a first spectral range comprising a wavelength having an energy at least equal to a dissociation energy of the active fluorination agent.

3. The method of claim 2, wherein a highest energy of the first spectral range is at most 100% greater than the dissociation energy of the active fluorination agent.

4. The method of claim 3, wherein the highest energy of the first spectral range is at most a band gap energy of the fluoride layer.

5. The method of claim 2, wherein a highest energy of the first spectral range is at most a band gap energy of the fluoride layer.

6. The method of claim 2, wherein the UV/VUV radiation comprises a second spectral range in an energy range of between 75% and 100% of a band gap energy of the fluoride layer.

7. The method of claim 1, wherein the UV/VUV radiation comprises a spectral range in an energy range of between 75% and 100% of a band gap energy of the fluoride layer.

8. The method of claim 1, wherein the fluoride layer comprises AlF₃.

9. The method of claim 1, wherein the fluoride layer is an AlF₃ layer.

10. The method of claim 1, wherein:
the UV/VUV radiation or further electromagnetic radiation additionally used to irradiate the fluoride layer comprises a spectral range to anneal a crystal defect of the fluoride layer; and
the spectral range at least partly overlaps with an absorption range of the at least one crystal defect.

11. The method of claim 1, wherein the fluoride layer is irradiated in a protective gas atmosphere.

12. The method of claim 1, wherein, when irradiating the fluoride layer, an oxygen concentration is less than 10 parts per million by volume.

13. The method of claim 1, wherein, when irradiating the fluoride layer, an H₂O concentration is less than 10 parts per million by volume.

14. The method of claim 1, wherein, when irradiating the fluoride layer, a partial pressure of the active fluorination agent is between 0.05 parts per million by volume (ppm V) and 10⁶ ppm V.

15. The method of claim 1, wherein, when irradiating the fluoride layer:
an oxygen concentration is less than 10 parts per million by volume (ppm V);
an H₂O concentration is less than 10 ppm V; and
a partial pressure of the active fluorination agent is between 0.05 ppm V and 10⁶ ppm V.

16. The method of claim 1, wherein, when irradiating the fluoride layer, a partial pressure of the active fluorination agent is adjusted to a target value.

17. The method of claim 1, wherein, when irradiating the fluoride layer, the fluoride layer is heated.

18. An optical element, comprising:
a fluoride layer prepared using the method of claim 1.

19. An optical arrangement, comprising:
an optical element prepared using the method of claim 1,
wherein the optical arrangement is a VUV lithography apparatus or a VUV wafer inspection system.

20. A device, comprising:
an aftertreatment chamber;
a supply unit configured to supply inert gas and an active fluorination agent into the aftertreatment chamber, an inner side of the aftertreatment chamber being resistant to the active fluorination agent and its conversion products; and
a UV/VUV radiation source configured so that, when an optical element comprising a fluoride layer is present in the aftertreatment chamber, the UV/VUV radiation source irradiates the fluoride layer with UV/VUV radiation in the presence of the active fluorination agent in the aftertreatment chamber.
